(19) United States
(12) Patent Application Publication
(10) Pub. No.: US 2026/0322390 A1
(43) Pub. Date: Oct. 15, 2026

(54) FRACTIONAL-ORDER DIFFERENCE ANALOG-TO-DIGITAL CONVERTER FOR NEURAL ACTION POTENTIAL ACQUISITION

(71) Applicant: TIANJIN UNIVERSITY, Tianjin (CN)

(72) Inventors: Biao SUN, Tianjin (CN); Chenguang ZHENG, Tianjin (CN)

(73) Assignee: TIANJIN UNIVERSITY, Tianjin (CN)

(21) Appl. No.: 19/556,790

(22) Filed: Mar. 4, 2026

Related U.S. Application Data
(63) Continuation of application No. PCT/CN2025/103731, filed on Jun. 26, 2025.

(30) Foreign Application Priority Data
Apr. 14, 2025 (CN) 202510465947.8

(51) Int. Cl. H03M 1/12

(52) U.S. Cl. CPC H03M 1/12

(57) ABSTRACT

Firstly, a fractional-order difference operator is designed to calculate any fractional-order incremental encoding, which can more effectively utilize the sparsity of neural action potentials, significantly improve a compression ratio of neural action potentials, and offers higher flexibility with adjustable difference-orders, adapting to more neural action potential acquisition application scenarios. Secondly, a fractional-order buffer module is designed to generate any fractional-order incremental encoding values in a concise and efficient manner. Finally, a serialized bitstream generator is designed to serialize and package fractional-order incremental data acquired from a plurality of parallel channels. This design not only offers high scalability for multi-channel acquisition but also reliably interfaces with subsequent synchronous clock wireless transmission systems, eliminating overhead and latency associated with synchronous-asynchronous interface coordination and further improving neural action potential acquisition efficiency.

### CROSS-REFERENCE TO RELATED APPLICATIONS

This application is a continuation of International Application No. PCT/CN2025/103731, filed on Jun. 26, 2025, which claims priority to Chinese Patent Application No. 202510465947.8, filed on Apr. 14, 2025. All of the aforementioned applications are incorporated herein by reference in their entireties.

### TECHNICAL FIELD

The present disclosure belongs to the technical field of brain-computer interfaces, and particularly a fractional-order difference analog-to-digital converter for neural action potential acquisition.

### BACKGROUND

As a disruptive technology in the interdisciplinary field of neuroscience and engineering, invasive brain-computer interfaces directly capture cortical electrical activity through implanted electrode arrays, reshaping the paradigm for rehabilitation in paralyzed patients and treatment of neurological dis-orders. This technology can not only analyze motor intention signals to help spinal cord injury patients operate robotic arms to complete grasping actions, but also intervene in abnormal electroencephalographic rhythms through closed-loop electrical stimulation intervention, providing precise treatment plans for Parkinson's disease tremor control. Its high spatiotemporal resolution signal decoding capability enables researchers to explore the neural circuit mechanisms of cognitive functions with single-neuron resolution, accelerating deep integration of brain-machine integration theory and clinical translation research.

In invasive systems, neural action potentials, as the core bioelectrical signals reflecting neuronal single-cell discharge, have their acquisition quality directly determining the decoding performance of brain-computer interfaces. These signals, generated by the conduction of neuronal action potentials, exhibit millivolt-level amplitude and millisecond-scale temporal duration characteristics. To precisely capture their discharge timing, microelectrode arrays must penetrate a cortical layer to reach vicinity of targeted neurons, using high-impedance probes and adaptive threshold detection techniques to isolate action potential waveforms. Due to the susceptibility of spike potential amplitude to changes in cellular membrane impedance, the system must integrate dynamic gain compensation modules and multi-channel signal alignment algorithms to maintain encoding consistency. However, this cellular-level electrophysiological recording imposes stricter requirements on electrode tip morphology, tissue-interface stability, and signal crosstalk suppression, as any distortion of action potential waveforms can lead to misinterpretation of neuronal ensemble coding information.

Traditional acquisition architectures commonly employ Nyquist Analog-to-Digital Converter (ADCs) for full-band uniform sampling of neural action potentials, facing severe energy efficiency challenges when implementing high-density multi-channel neural action potential recording. Since the neural action potentials, as characteristic signals of single-neuron action potentials, have their effective information concentrated in a high-frequency band of 500 Hz-8 kHz and exhibit sub-millisecond transient discharge characteristics, the use of a fixed-rate broadband sampling strategy leads to signal sparsity issues, and approximately 85% of the sampled data only records baseline noise. This not only results in inefficient utilization of analog-to-digital conversion resources but also causes an exponential increase in the power density of the implanted system. When the number of microelectrode channels is expanded to 256, the static power consumption of the front-end sampling module may exceed the 20-milliwatt safety threshold, causing local tissue thermal deposition effects that not only accelerate electrode-tissue interface impedance drift but may also affect the normal discharge patterns of neighboring neurons.

To break through the energy-efficiency bottleneck, event-driven incremental encoding analog-to-digital conversion technology (such as Delta-ADC) has emerged. This scheme innovatively introduces a dynamic threshold comparison mechanism, triggering quantization operations only when the signal change amplitude exceeds a preset threshold. This adaptive sampling strategy fully exploits the temporal sparsity of neural action potentials, enabling data throughput reductions of over 82% in scenarios such as Parkinson's disease monitoring and rhythm acquisition. By constructing a multi-level differential encoding tree, the system can simultaneously extract amplitude transient and slope variation information from the signals, significantly reducing single-channel power consumption while maintaining action potential waveform details, thereby extending the battery life of implanted devices.

However, despite the theoretical ability of Delta-ADCs to significantly improve acquisition efficiency, existing implementations still face several key issues. Firstly, the incremental encoding method used by Delta-ADCs is not always superior to traditional ADCs based on Nyquist sampling. In certain application scenarios, especially when signals change frequently or are complex, the performance of Delta-ADCs may be inferior to that of traditional successive approximation ADCs. Furthermore, existing Delta-ADCs generally employ 1-order difference calculations to generate 1-order incremental encoding. However, the 1-order incremental encoding does not fully exploit the sparsity of neural action potentials, resulting in limited compression effects and insufficiently enhanced acquisition efficiency. Finally, most existing Delta-ADC systems employ asynchronous sampling modes, whereas wireless brain-computer interface systems typically employ synchronous digital processing schemes. This leads to significant overhead and latency in system interface coordination, further affecting overall performance and energy efficiency.

Thus, to meet the demands of modern brain-computer interfaces for efficient acquisition, low-power transmission, and high-quality signal restoration, designing a new type of analog-to-digital converter that can effectively compress neural action potential signals, enhance acquisition efficiency, and adapt to wireless transmission requirements is crucial. This design must not only fully exploit the sparsity characteristics of neural action potentials but also consider system power consumption, sampling efficiency, and compatibility with subsequent processing modules.

### SUMMARY

To overcome the inefficiency of neural action potential acquisition in existing technologies, the present disclosure provides a fractional-order difference analog-to-digital converter (FOD-ADC) for neural action potential acquisition, which comprehensively improves signal acquisition efficiency while maintaining a simple circuit topology. First, a fractional-order difference operator is designed to calculate any fractional-order incremental encoding, which as compared to the existing 1-order incremental encoding, can not only more effectively utilize the sparsity of neural action potentials, significantly improve a compression ratio of neural action potentials, but offers higher flexibility with adjustable difference-orders, adapting to more neural action potential acquisition application scenarios. Second, a fractional-order buffer module is designed to generate any fractional-order incremental encoding values in a concise and efficient manner. Finally, a serialized bitstream generator is designed to serialize and package fractional-order incremental data acquired from a plurality of parallel channels. This design not only offers high scalability for multi-channel acquisition but also reliably interfaces with subsequent synchronous clock wireless transmission systems, eliminating overhead and latency associated with synchronous-asynchronous interface coordination and further improving neural action potential acquisition efficiency.

The present disclosure relates to a fractional-order difference analog-to-digital converter for neural action potential acquisition, where the circuit includes a multiplexer, a fractional-order buffer module, a DAC controller, a DAC, a comparator, an incremental counter, and a serialized bitstream generator. The multiplexer is controlled by a global clock CLKADC of the FOD-ADC to switch acquisition channels in each clock cycle and stabilize the currently acquired signal to support multi-channel parallel acquisition.

Furthermore, the fractional-order buffer module is controlled by the global clock CLKADC of the FOD-ADC and is responsible for storing and outputting the previously acquired value for each channel to support the calculation of any fractional-order incremental encoding.

Furthermore, the DAC controller reads the previously acquired value from the fractional-order buffer module and generates a DAC control code in combination with an output of the incremental counter.

Furthermore, the DAC reads the DAC control code output by the DAC controller, converts the DAC control code into a signal to be compared, and after a plurality of comparisons, the final DAC output is stored as the currently acquired value for the current channel in the fractional-order buffer module.

Furthermore, the comparator compares a signal to be acquired output by the multiplexer with the signal to be compared output by the DAC and inputs a comparison result into the incremental counter for increment counting.

Furthermore, the incremental counter, controlled by the global clock CLKADC of the FOD-ADC, reads an output result of the comparator in each clock cycle, calculates the fractional-order increment between the currently acquired signal and the previously acquired value, and transmits the increment to the DAC controller and serialized bitstream generator.

Furthermore, the serialized bitstream generator, controlled by the global clock CLKADC of the FOD-ADC, stores and converts the signal increment output by the incremental counter into a bitstream in each clock cycle to achieve data compression and serialize and package the data to ensure synchronous data transmission, generating a final bitstream output by the FOD-ADC.

Provided is a fractional-order difference analog-to-digital converter for neural action potential acquisition. Firstly, a fractional-order difference operator is designed to calculate any fractional-order incremental encoding, which can more effectively utilize the sparsity of neural action potentials, significantly improve a compression ratio of neural action potentials, and offers higher flexibility with adjustable difference-orders, adapting to more neural action potential acquisition application scenarios. Secondly, a fractional-order buffer module is designed to generate any fractional-order incremental encoding values in a concise and efficient manner. Finally, a serialized bitstream generator is designed to serialize and package fractional-order incremental data acquired from a plurality of parallel channels. This design not only offers high scalability for multi-channel acquisition but also reliably interfaces with subsequent synchronous clock wireless transmission systems, eliminating overhead and latency associated with synchronous-asynchronous interface coordination and further improving neural action potential acquisition efficiency.

### BRIEF DESCRIPTION OF THE DRAWINGS

To more clearly illustrate the technical solutions in the embodiments of the present disclosure, the accompanying drawings required in the description of the embodiments or the prior art will be briefly introduced below. Obviously, the accompanying drawings described below are merely some embodiments of the present disclosure, and for a person skilled in the art, other accompanying drawings may also be obtained based on these drawings without making creative efforts. In the drawings:

FIG. 1 illustrates an overall architecture of a fractional-order difference analog-to-digital converter for neural action potential acquisition according to the present disclosure;

FIG. 2 is a schematic diagram of a fractional-order buffer module;

FIG. 3 depicts an execution process of a fractional-order buffer module;

FIG. 4 is a schematic diagram of an operating principle of a DAC controller;

FIG. 5 is a structural diagram of a DAC;

FIG. 6 is a structural diagram of a comparator;

FIG. 7 is a schematic diagram of an operating principle of an incremental counter;

FIG. 8 is an example timing diagram of an incremental counter;

FIG. 9 is a schematic diagram of an operating principle of a serialized bitstream generator;

FIG. 10 shows data results acquired by two types of ADCs;

FIG. 11 shows normalized results of a data acquired by two types of ADCs;

FIG. 12 shows results of converting a data acquired by two types of ADCs into bitstreams; and

FIG. 13 shows a count of 0s and 1s in a bitstream, as well as a total count of binary values.

### DETAILED DESCRIPTION OF THE EMBODIMENTS

In the following description, for illustration rather than limitation, specific details such as specific system configurations and technologies are set forth to facilitate a thorough understanding of the embodiments of the present disclosure. However, it will be apparent to a person skilled in the art that the present disclosure may also be practiced in other embodiments without these specific details. In other instances, detailed descriptions of well-known systems, devices, circuits, and methods are omitted so as not to obscure the description of the present disclosure with unnecessary details.

For an N-point neural spike time series signal X=[x₁, x₂, . . . , x_{N}]^{T}, its f-order fractional difference operator is defined as:

$$Y = {D}^{f} X = {\sum }_{j = 0}^{∞} {( - 1 )}^{j} \frac{Γ ( f + 1 )}{j ! Γ ( f - j + 1 )} {x}_{i + j} , i = 1 , 2 , ⋯ , N .$$

where xᵢ is an ith element in a signal X, f is any fraction greater than 0, j! represents a factorial of j, Γ(⋅) represents a GAMMA function, D^{f} is a f-order fractional difference operator, and Y is an incremental value after f-order fractional difference calculation of the signal X. Fractional-order difference involves an infinite series, but in practice, due to the finite length of neural spike signals, truncation is necessary. Therefore, truncating to the (g=[f]+1)-th item, the f-order fractional difference operator is defined as:

$$Y = {D}^{f} X = {\sum }_{j = 0}^{g} {( - 1 )}^{j} \frac{Γ ( f + 1 )}{j ! Γ ( f - j + 1 )} {x}_{i + j} , i = 1 , 2 , ⋯ , N .$$

from the above formula, it can be seen that to calculate the f-order increment of the currently acquired data point, the values of the previous g acquired data points are required.

Taking a 1.3-order fractional difference operator as an example, its matrix form is as follows:

$${D}^{1.3} = [ \begin{matrix}0.195 & - 1.3 & 1 & 0 & ⋯ & 0 \\ 0 & 0.195 & - 1.3 & 1 & ⋯ & 0 \\ ⋮ & ⋮ & ⋮ & ⋮ & ⋱ & ⋮ \\ 0 & 0 & ⋯ & 0.195 & - 1.3 & 1\end{matrix} ] .$$

to calculate the 1.3-order fractional-order difference incremental value of the currently acquired neural action potential data point, the values of the previous two acquired neural action potential data points must first be obtained. After calculation, the 1.3-order subtrahend yᵢ=1.3xᵢ₋₁−0.195xᵢ₋₂ is obtained, and then xᵢ is subtracted yᵢ from the currently acquired data point to obtain the 1.3-order difference incremental value zᵢ=xᵢ−yᵢ=xᵢ−(1.3xᵢ₋₁−0.195xᵢ₋₂).

Taking a 2.5-order fractional difference operator as an example, its matrix form is as follows:

$${D}^{2.5} = [ \begin{matrix}- 2.1875 & 4.375 & - 3.5 & 0 & … & 0 \\ 0 & - 2.1875 & 4.375 & 1 & … & 0 \\ ⋮ & ⋮ & ⋮ & ⋮ & ⋱ & ⋮ \\ 0 & 0 & - 2.1875 & 4.375 & - 3.5 & 1\end{matrix} ]$$

to calculate the 2.5-order fractional-order difference incremental value of the currently acquired neural action potential data point, the values of the previous 3 acquired data points must first be obtained. After calculation, the 2.5-order subtrahend yᵢ=3.5xᵢ₋₁−4.375xᵢ₋₂+2.1875xᵢ₋₃ is obtained, and then xᵢ is subtracted yᵢ from the currently acquired data point to obtain the 2.5-order difference incremental value zᵢ=xᵢ−yᵢ=xᵢ−(3.5xᵢ₋₁−4.375xᵢ₋₂+2.1875xᵢ₋₃).

To achieve f-order increment acquisition, the present disclosure proposes a fractional-order difference analog-to-digital converter for neural action potential acquisition, with its overall architecture shown in FIG. 1. The device consists of a multiplexer, a fractional-order buffer module, a DAC controller, a DAC, a comparator, an incremental counter, and a serialized bitstream generator.

The multiplexer is controlled by a global clock CLKADC of the FOD-ADC, switching acquisition channels every clock cycle and stabilizing the currently acquired signal after channel switching to support multi-channel parallel acquisition. The multiplexer in this circuit employs a standard time-division multiplexing structure, allowing signals from L channels to share a single physical channel for transmission and sequentially occupy this channel in different CLKADC cycles to achieve efficient data acquisition.

In the present disclosure, the time-division multiplexing structure is implemented through a multi-way switch circuit, with the switch position changing once per clock cycle to select different acquisition channels. After the multi-way switch, the signal enters a sample-and-hold circuit, where a switched-capacitor circuit is configured to physically implement signal holding, ensuring signal stability during the acquisition process and guaranteeing the accuracy and reliability of subsequent acquisitions.

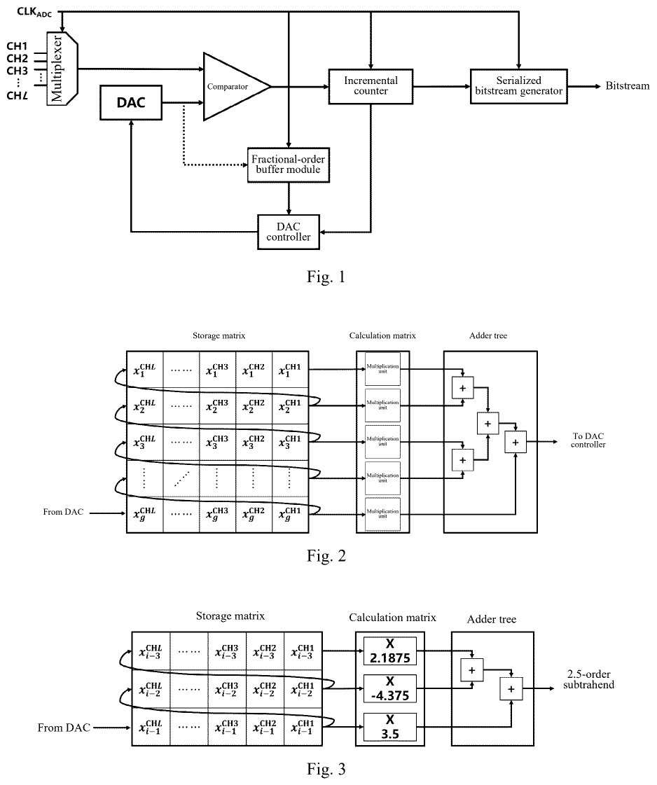

As shown in FIG. 2, the fractional-order buffer module, controlled by the global clock CLKADC of the FOD-ADC, is responsible for storing and outputting the values of previously g acquired data points for each channel to support the calculation of the f-order subtrahend while avoiding the complexity of traditional first-in-first-out buffer structures.

Specifically, the module includes three parts: a storage matrix, a computation matrix, and an adder tree. The storage matrix contains g rows and L columns. In each clock cycle, data input from the DAC is input to the left side of the g-th row, and the data on the far right of each row is shifted out of the storage matrix and input into the computation matrix for calculation. Simultaneously, the data in the storage matrix performs circular shifting, where the data shifted out from a lower row is shifted into the left side of the upper row. Except for the g-th row, which can receive data input from the DAC, data in other rows can only be shifted in from the corresponding lower row and cannot receive external input data from the module. Thus, the storage matrix forms a 1-input-g-output structure. This structure is designed to work with the computation matrix to read data in a fixed format to avoid increased circuit complexity and power consumption due to frequent switching of readout ports.

The computation matrix consists of a series of multiplication units that multiply the data retrieved from the storage matrix by the corresponding differential operator coefficients and then input the results into the adder tree. The adder tree accumulates the data that has been multiplied by the coefficients to obtain a f-order subtrahend and outputs the f-order subtrahend to the DAC controller to complete a task of the fractional-order buffer module.

The fractional-order buffer module, controlled by the global clock CLKADC of the FOD-ADC, receives one data point, performs one storage matrix read, one calculation, and one accumulation per cycle. Taking the 2.5-order FOD-ADC as an example, assuming it is the i-th cycle and the first channel is acquired to obtain an acquired value

$${x}_{i}^{CH 1} ,$$

where the 2.5-order subtrahend is

$$3.5 {x}_{i - 1}^{CH 1} - 4.375 {x}_{i - 2}^{CH 1} + 2.1875 {x}_{i - 3}^{CH 1} ,$$

and the execution process is as shown in FIG. 3 as follows:

Assuming the current data stored in the storage matrix is:

$$[ \begin{matrix}{x}_{i - 3}^{C H L} & … & {x}_{i - 3}^{CH 3} & {x}_{i - 3}^{CH 2} & {x}_{i - 3}^{CH 1} \\ {x}_{i - 2}^{C H L} & … & {x}_{i - 2}^{CH 3} & {x}_{i - 2}^{CH 2} & {x}_{i - 2}^{CH 1} \\ {x}_{i - 1}^{CHL} & … & {x}_{i - 1}^{CH 3} & {x}_{i - 1}^{CH 2} & {x}_{i - 1}^{CH 1}\end{matrix} ]$$

Step 1: retrieving the first three acquired values of

$${x}_{i - 3}^{CH 1} , {x}_{i - 2}^{CH 1} and {x}_{i - 1}^{CH 1}$$

of the first channel from the three output ports of the storage matrix and input these three acquired values into the computation matrix for calculation operations.

Step 2: activating three multiplication units in the computation matrix, numbered 1, 2, and 3, respectively.

$${x}_{i - 3}^{C H 1}$$

is input into a multiplication unit 1 and multiplied by a coefficient 2.1875 to obtain

$$2.1875 {x}_{i - 3}^{CH 1} . {x}_{i - 2}^{CH 1}$$

is input into a multiplication unit 2 and multiplied by a coefficient −4.375 to obtain

$$- 4.375 {x}_{i - 2}^{CH 1} . {x}_{i - 1}^{CH 1}$$

is input into a multiplication unit 3 and multiplied by a coefficient 3.5 to obtain

$$3.5 {x}_{i - 3}^{CH 1} .$$

Step 3: inputting the results of the three multiplication units into the adder tree for accumulation to obtain a 2.5-order subtrahend

$$3.5 {x}_{i - 1}^{CH 1} - 4.375 {x}_{i - 2}^{CH 1} + 2.1875 {x}_{i - 3}^{CH 1} .$$

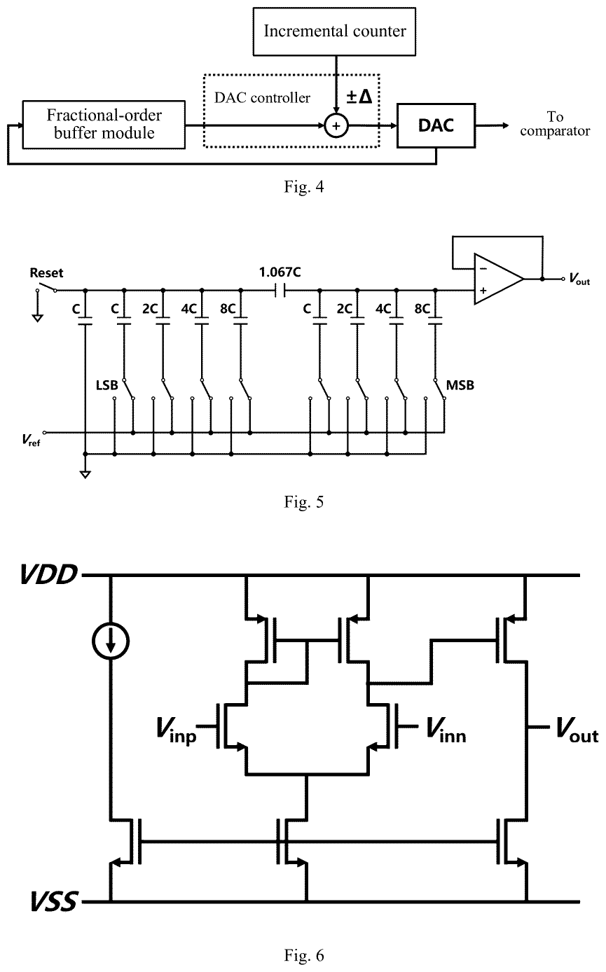

As shown in FIG. 4, the DAC controller is configured to read an f-order subtrahend output by the fractional-order buffer module and, in combination with the output of the incremental counter, generates the DAC control code.

Specifically, controlled by the global clock CLKADC, the FOD-ADC will sequentially acquire data from the L channel, acquiring data from one channel per clock cycle. Assuming the first channel is acquired and an acquired value of

$${x}_{i}^{CH 1}$$

is obtained, the workflow of the DAC controller is as follows:

Step 1: Calculate an f-order subtrahend yᵢ through a fractional-order buffer module.

Step 2: Input, by the incremental counter, an incremental value kΔ and adding the incremental value to the f-order subtrahend yᵢ to obtain a value yᵢ+kΔ to be compared, where Δ is a minimum quantization unit of the FOD-ADC; an initial value of the incremental value is 0. The initial value of the incremental value is 0Δ.

Step 3: Use the value yᵢ+kΔ to be compared as the DAC control code, input the DAC control code into the DAC, and convert the DAC control code into a corresponding signal to be compared.

Step 4: Input the signal to be compared into the comparator and compare the signal to be compared with the signal to be acquired, where if the signal to be acquired is greater than the signal to be compared, the incremental counter increments by 1Δ and the incremental value becomes (k+1)Δ, otherwise, the incremental counter decrements by 1Δ and the incremental value becomes (k−1)Δ.

Step 5: Execute the following steps in a loop: repeat steps 2 to 4 until a difference between the signal to be acquired and the signal to be compared is less than 1Δ, at which point the loop is stopped, and use the current DAC output as the acquired value

$${x}_{i}^{CH 1} .$$

Step 6: storing

$${x}_{i}^{CH 1}$$

in the fractional-order buffer module and updating the values in each row of the fractional-order buffer module.

Subsequently, the above process can be continued to acquire data from the second to the L-th channel. After acquiring the L-th channel, return to acquire the first channel.

As shown in FIG. 5, the DAC reads the DAC control code output by the DAC controller, converts the DAC control code into a signal to be compared, and after a plurality of comparisons, a final DAC output is stored as a currently acquired value for a current channel in the fractional-order buffer module.

Specifically, the DAC employs an 8-bit capacitive voltage-dividing structure composed of an array of eight weighted capacitors with capacitances of C, 2C, 4C, 8C, C, 2C, 4C, and 8C, respectively. Before conversion begins, the Reset switch is closed to ground upper plates of all capacitors and discharge the capacitor array. In the conversion phase, the Reset switch is opened, and the lower plates of the eight binary-weighted capacitors are connected to Vref or ground according to the control code. Additionally, one 1.067-C attenuation capacitor is incorporated to divide the capacitor array into two parts to reduce the variety of capacitors. The rightmost side of the DAC forms a voltage follower structure through one operational amplifier with negative feedback to isolate the capacitor array from the DAC output to reduce output impedance and enhance load-carrying capacity.

As shown in FIG. 6, the comparator compares a signal to be acquired output by the multiplexer with the signal to be compared output by the DAC and inputs a comparison result into the incremental counter for increment counting. To reduce power consumption, the FOD-ADC employs a dynamic comparator. A signal to be acquired is input from a Vinp terminal, a signal to be compared is input from a Vinn terminal, and a comparison result is output from a Vout terminal.

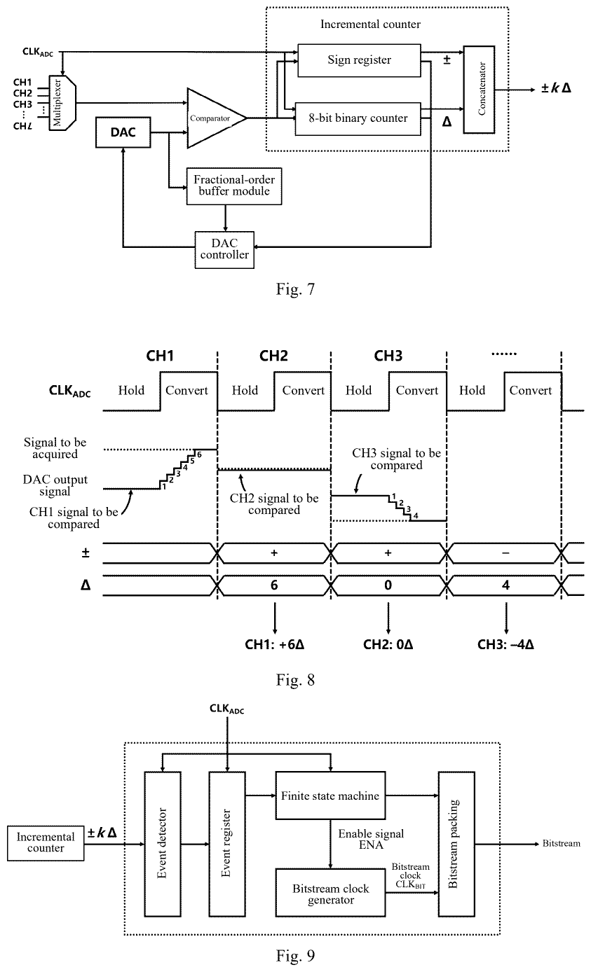

As shown in FIG. 7, the incremental counter, controlled by the global clock CLKADC of the FOD-ADC, reads an output result of the comparator in each clock cycle, calculates the fractional-order increment between the currently acquired signal and the previously acquired value, and transmits the increment to the DAC controller and serialized bitstream generator.

Specifically, the incremental counter includes two modules: a sign register composed of a 1-bit register circuit for storing a sign of the incremental value, and an 8-bit binary counter composed of eight D flip-flops for storing a magnitude of the incremental value.

The operating method of the incremental counter is as follows: the initial value of the incremental value is 0Δ. When the comparator output is positive, it is determined that the signal to be acquired is greater than the signal to be compared, the incremental counter increments by 1Δ, the sign register is set to positive, and the incremental value becomes (0+1)Δ. When the comparator output is negative, it is determined that the signal to be acquired is less than the signal to be compared, the incremental counter decrements by 1Δ, the sign register is set to negative, and the incremental value becomes (0-1)Δ. After each determination, the incremental value is output to the DAC controller for generating the DAC control code. The above determination steps are repeated until a difference between the signal to be acquired and the signal to be compared is less than 1Δ. At this point, the loop is stopped, and the sign in the sign register is concatenated with the value in the 8-bit binary counter to obtain a final fractional-order incremental value.

As shown in FIG. 8, an example timing diagram of the incremental counter is provided. In each cycle of the global clock CLKADC, one channel is acquired. In each clock cycle, the output of the multiplexer remains stable for the incremental counter to perform analog-to-digital conversion.

In the first cycle, the incremental counter performs analog-to-digital conversion on a CH1 channel. In a low-level period of CLKADC, both the signal to be acquired and the DAC output signal remain stable, with the DAC output signal being the signal to be compared for the CH1 channel. In the high-level period of the CLKADC, the incremental counter begins analog-to-digital conversion. It is found from the first comparison that the signal to be compared is less than the signal to be acquired, so increment 1Δ is added, and the comparison is continued, after six additions of 1Δ, the difference between the signal to be compared and the signal to be acquired is less than 1Δ, at which point the conversion is completed. At the beginning of the next CLKADC cycle, the incremental counter outputs the incremental value for the CH1 channel as +6Δ.

In the second cycle, the incremental counter performs analog-to-digital conversion on a CH2 channel. In a low-level period of CLKADC, both the signal to be acquired and the DAC output signal remain stable, with the DAC output signal being the signal to be compared for the CH2 channel. In the high-level period of the CLKADC, the incremental counter begins analog-to-digital conversion. The first comparison reveals that the difference between the signal to be compared and the signal to be acquired is less than 1Δ, at which point the conversion is complete. At the beginning of the next CLKADC cycle, the incremental counter outputs the incremental value for the CH1 channel as 0Δ. At this point, it is considered that there is no increment between the current and previously acquireds for the CH2 channel.

In the third cycle, the incremental counter performs analog-to-digital conversion on a CH3 channel. In a low-level period of CLKADC, both the signal to be acquired and the DAC output signal remain stable, with the DAC output signal being the signal to be compared for the CH3 channel. In the high-level period of the CLKADC, the incremental counter begins analog-to-digital conversion. It is found from the first comparison that the signal to be compared is greater than the signal to be acquired, so increment 1Δ is subtracted, and the comparison is continued, after 4 subtractions of 1Δ, the difference between the signal to be compared and the signal to be acquired is less than 1Δ, at which point the conversion is completed. At the beginning of the next CLKADC cycle, the incremental counter outputs the incremental value for the CH1 channel as −4Δ.

Other channels undergo analog-to-digital conversion cycle by cycle according to the above conversion rules.

As shown in FIG. 9, the serialized bitstream generator, controlled by the global clock CLKADC of the FOD-ADC, stores and converts the signal increment output by the incremental counter into a bitstream in each clock cycle to achieve data compression and serialize and package the data to ensure synchronous data transmission, generating a final bitstream output by the FOD-ADC.

Specifically, on a rising edge of each global clock CLKADC, the event detector reads the incremental value from the incremental counter and determines whether this incremental value forms a fractional-order incremental event. When the incremental value is not 0Δ, it is indicated that the currently acquired signal is different from the signal to be compared, and thus it can be determined as a fractional-order incremental event. At this point, the incremental value is stored in the event register.

Each fractional-order incremental event requires 9+log₂ L bit storage space, where log₂ L bits are used for numbering the L channel, 1 bit is used for the sign of incremental value, and 8 bits are used for storing the amplitude of the incremental value. Additionally, the system is equipped with one 9+log₂ L bit shadow memory for parallel data buffering and processing to improve data throughput efficiency.

After all L channels have completed one acquisition, one complete data acquisition frame is formed. Upon completion of each acquisition frame, a finite state machine generates one enable signal ENA and inputs the signal into a bitstream clock generator. The clock generator, equipped with a built-in ring oscillator, provides the clock CLKBIT for bitstream packer.

Then, the finite state machine scans the data in the event register and performs bitstream packer based on the CLKBIT clock to ultimately generate a FOD-ADC data bitstream.

The present disclosure proposes a comparison between the FOD-ADC and the current state-of-the-art Nyquist ADC. The experimental setup is as follows: after anesthetization, a subject animal remains stationary in a cage, with electrodes implanted in its head to lead out two electrode channels. Identical neural action potentials are present on each electrode channel, with Channel 1 using a Nyquist ADC for acquisition and Channel 2 using the FOD-ADC for acquisition, and a differential-order of the FOD-ADC is selected as 1.3, 2.5, and 3.7 for a comprehensive comparison. The acquired data is transmitted to a computer via wired connection for analysis.

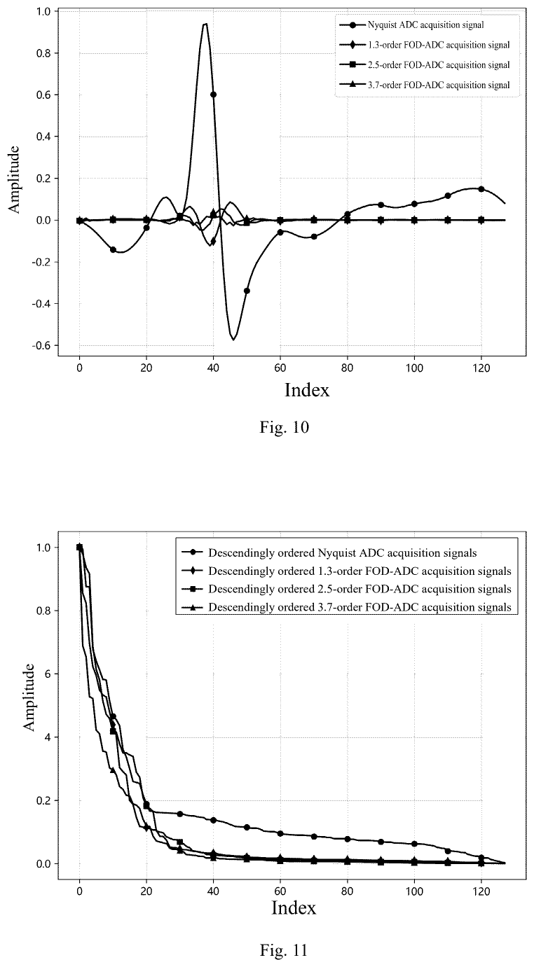

The data acquired by the two types of ADCs is as shown in FIG. 10, revealing that the data acquired by the Nyquist ADC exhibits greater volatility and larger amplitudes, while the data acquired by the FOD-ADC shows less volatility, with most acquired values being very close to 0 and only a few acquired values being relatively large, indicating higher sparsity.

The data acquired by the two ADCs is sorted in a descending-order and performed normalization processing to obtain a result as shown in FIG. 11. It can be seen that the sparsity of the data acquired by the FOD-ADC is significantly higher than that of the data acquired by the Nyquist ADC.

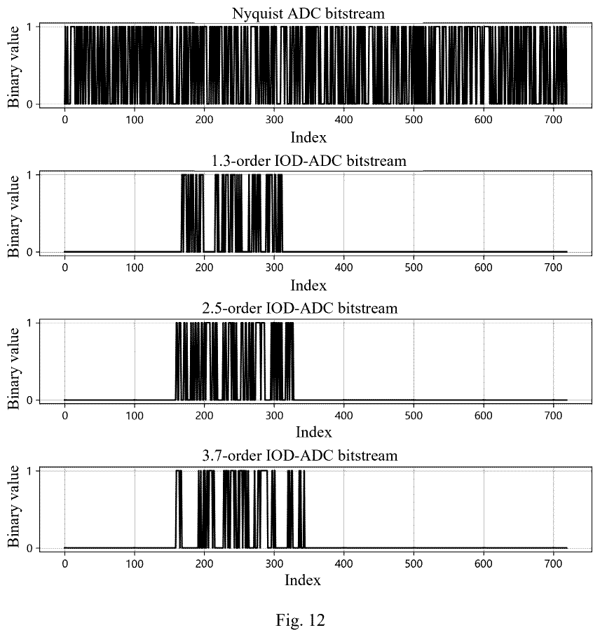

The data acquired by the two types of ADCs is converted into a bitstream, as shown in FIG. 12. It can be seen that the bitstream of the FOD-ADC is sparser than that of the Nyquist ADC.

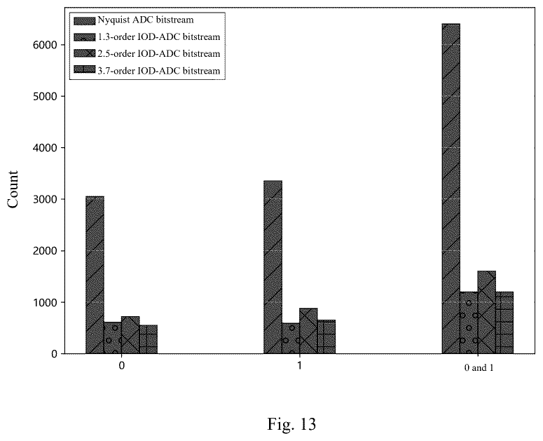

The data acquired by the two types of ADCs is converted into a bitstream, and the count of 0s and Is in the bitstreams as well as the total count of binary values are counted, as shown in FIG. 13. It can be concluded that the data volume of the 1.3-order FOD-ADC bitstream is 18.1% of that of the Nyquist ADC bitstream, the data volume of the 2.5-order FOD-ADC bitstream is 24.6% of that of the Nyquist ADC bitstream, and the data volume of the 3.7-order FOD-ADC bitstream is 18.2% of that of the Nyquist ADC bitstream.

As described above, the data volume required for transmission by the FOD-ADC is significantly lower than that required for transmission by the Nyquist ADC to offer higher energy efficiency.

It should be understood that the sequence numbers of the steps in the foregoing embodiments do not imply the-order of execution; the execution-order of each process shall be determined based on its functions and inherent logic, and shall not constitute any limitation on the implementation process of the embodiments of the present disclosure.

A person skilled in the art can clearly understand that, for the convenience and conciseness of description, the division of the above-mentioned functional units and modules is merely given as an example. In practice, the above-mentioned functions may be allocated to different functional units and modules as needed to be completed, that is, the internal structure of the device may be divided into different functional units or modules to fulfill all or part of the functions described above. The functional units and modules in the embodiments may be integrated into one processing unit, or each unit may exist physically independently, or two or more units may be integrated into one unit. The above-mentioned integrated units may be implemented either in the form of hardware or in the form of software functional units. In addition, the specific names of the functional units and modules are merely for the convenience of distinguishing between each other, and are not intended to limit the protection scope of the present application. For the specific working processes of the units and modules in the above-mentioned system, reference may be made to the corresponding processes in the foregoing method embodiments, and they will not be repeated herein.

The parts not elaborated on or recorded in one embodiment, reference may be made to the relevant descriptions in other embodiments.

A person skilled in the art may recognize that the units and algorithm steps of each example described in conjunction with the embodiments disclosed herein can be implemented by means of electronic hardware, or a combination of computer software and electronic hardware. Whether these functions are executed in a hardware or software manner depends on the specific application and design constraints of the technical solution. A person skilled in the art may employ different methods to implement the described functions for each specific application, but such implementation shall not be deemed to be beyond the scope of the present disclosure.

In the embodiments provided by the present disclosure, it should be understood that the disclosed devices/terminal equipment and methods may be implemented in other manners. For example, the embodiments of the devices/terminal equipment described above are merely illustrative; for instance, the division of the modules or units is merely a logical function division, and there may be other division manners in actual implementation—for example, a plurality of units or components may be combined or integrated into another system, or some features may be omitted or not implemented. On the other hand, the coupling, direct coupling, or communicative connection between them as shown or discussed may be through some interfaces, and the indirect coupling or communicative connection between devices or units may be in electrical, mechanical, or other forms.

The units described as separate components may be or may not be physically separated, and the components shown as units may be or may not be physical units—that is, they may be in one place, or may be distributed across multiple network units. Some or all the units may be selected according to actual needs to achieve the objectives of the solution of the present embodiment.

In addition, each functional unit in each embodiment of the present disclosure may be integrated into one processing unit, or each unit may exist physically independently, or two or more units may be integrated into one unit. The above-mentioned integrated units may be implemented either in the form of hardware or in the form of software functional units.

If the integrated modules/units are implemented in the form of software functional units and sold or used as independent products, they may be stored in a computer-readable storage medium. Based on such an understanding, all or part of the processes in the methods of the foregoing embodiments implemented by the present disclosure may also be completed by instructing the relevant hardware through a computer program. The computer program may be stored in a computer-readable storage medium, and when the computer program is executed by a processor, it can implement the steps of each of the foregoing method embodiments. The computer program includes computer program code, which may be in the form of source code, object code, executable files, or certain intermediate forms, etc. The computer-readable medium may include: any entity or device capable of carrying the computer program code, recording medium, USB flash drives, mobile hard disks, magnetic disks, optical disks, computer memory, Read-Only Memory (ROM), Random Access Memory (RAM), carrier signals, telecommunication signals, and software distribution media, etc. It should be noted that the content contained in the computer-readable medium may be appropriately added or deleted in accordance with the requirements of legislation and patent practice in the jurisdiction; for example, in some jurisdictions, according to legislation and patent practice, the computer-readable medium does not include carrier signals and telecommunication signals.

The foregoing embodiments are merely intended to illustrate the technical solutions of the present disclosure, but not to limit them. Although the present disclosure has been described in detail with reference to the foregoing embodiments, a person skilled in the art should understand that they may still modify the technical solutions recorded in the foregoing embodiments, or equivalently replace some of the technical features therein; and such modifications or replacements do not cause the essence of the corresponding technical solutions to depart from the spirit and scope of the technical solutions of the embodiments of the present disclosure, and all shall be included within the protection scope of the present disclosure.

What is claimed is:

1. A fractional-order difference analog-to-digital converter (FOD-ADC) for neural action potential acquisition, wherein the FOD-ADC comprises a multiplexer, a fractional-order buffer module, a digital-to-analog converter (DAC) controller, a DAC, a comparator, an incremental counter, and a serialized bitstream generator, and the FOD-ADC is configured to acquire neural action potential signals;
the multiplexer, the fractional-order buffer module, the incremental counter, and the serialized bitstream generator are all controlled by a global clock CLKADC of the FOD-ADC to perform respective functions thereof;
the multiplexer switches acquisition channels in each clock cycle and stabilizes a currently acquired signal to support multi-channel parallel acquisition;
the fractional-order buffer module stores and outputs a previously acquired value for each channel to support calculation of any fractional-order incremental encoding;
the DAC controller reads the previously acquired value from the fractional-order buffer module and generates a DAC control code in combination with an output of the incremental counter;
the DAC reads the DAC control code output by the DAC controller, converts the DAC control code into a signal to be compared, and after a plurality of comparisons, a final DAC output is stored as a currently acquired value for a current channel in the fractional-order buffer module;
the comparator compares a signal to be acquired output by the multiplexer with the signal to be compared output by the DAC and inputs a comparison result into the incremental counter for increment counting;
the incremental counter, in each clock cycle, reads an output result of the comparator, calculates the fractional-order increment between the currently acquired signal and the previously acquired value, and transmits the increment to the DAC controller and the serialized bitstream generator; and
the serialized bitstream generator, in each clock cycle, stores and converts the signal increment output by the incremental counter into a bitstream and generates the final bitstream output by the FOD-ADC.

2. The fractional-order difference analog-to-digital converter according to claim 1, wherein the multiplexer employs a time-division multiplexing structure, the time-division multiplexing structure is implemented through a multi-channel switch circuit, and the switch position is toggled once per clock cycle to select different acquisition channels.

3. The fractional-order difference analog-to-digital converter according to claim 1, wherein the fractional-order buffer module comprises three parts: a storage matrix, a computation matrix, and an adder tree;
the storage matrix comprises g rows and L columns; in each clock cycle, data input from the DAC is fed into a left side of a g-th row, and data at a rightmost end of each row is shifted out of the storage matrix and input into the computation matrix for calculation; data within the storage matrix performs circular shifting;
the computation matrix multiplies the data retrieved from the storage matrix by the corresponding fractional-order difference operator coefficients and then inputs the data into the adder tree; and
the adder tree accumulates the data that has been multiplied by the coefficients to obtain an f-order subtrahend and outputs the f-order subtrahend to the DAC controller to complete a task of the fractional-order buffer module.

4. The fractional-order difference analog-to-digital converter according to claim 1, wherein a workflow of the DAC controller is as follows:
step 1: calculating the f-order subtrahend yᵢ through the fractional-order buffer module;
step 2: obtaining an incremental value kΔ from the incremental counter and adding the incremental value to the f-order subtrahend yᵢ to obtain a value yᵢ+kΔ to be compared, wherein Δ is a minimum quantization unit of the FOD-ADC; and an initial value of the incremental value is 04;
step 3: using the value yᵢ+kΔ to be compared as the DAC control code, inputting the DAC control code into the DAC, and converting the DAC control code into a corresponding signal to be compared;
step 4: inputting the signal to be compared into the comparator and comparing the signal to be compared with the signal to be acquired, wherein if the signal to be acquired is greater than the signal to be compared, the incremental counter increments by 1Δ and the incremental value becomes (k+1)Δ, otherwise, the incremental counter decrements by 1Δ and the incremental value becomes (k−1)Δ;
step 5: executing the following steps in a loop: repeating steps 2 to 4 until a difference between the signal to be acquired and the signal to be compared is less than 1Δ, at which point the loop is stopped, and using the current DAC output as the acquired value
$${x}_{i}^{CH 1} ;$$
and
step 6: storing
$${x}_{i}^{CH 1}$$
in the fractional-order buffer module and updating the values in each row of the fractional-order buffer module.

5. The fractional-order difference analog-to-digital converter according to claim 1, wherein the incremental counter comprises a sign register and an 8-bit binary counter, the sign register comprises a 1-bit register circuit configured to store a sign of the incremental value, and the 8-bit binary counter comprises 8 D flip-flops configured to store an amplitude of the incremental value.

6. The fractional-order difference analog-to-digital converter according to claim 5, wherein the incremental counter operates as follows: the initial value of the incremental value is 0Δ; when an output of the comparator is positive, it is determined that the signal to be acquired is greater than the signal to be compared, the incremental counter increments by 1Δ, the sign register is set to positive, and the incremental value becomes (0+1)Δ; when the output of comparator is negative, it is determined that the signal to be acquired is less than the signal to be compared, the incremental counter decrements by 1Δ, the sign register is set to negative, and the incremental value becomes (0-1)Δ; after each determination, the incremental value is output to the DAC controller to generate the DAC control code; the above determination steps are repeated until a difference between the signal to be acquired and the signal to be compared is less than 1Δ, at which point the loop is stopped, and the sign in the sign register and the value in the 8-bit binary counter are concatenated to obtain a final fractional-order incremental value.

7. The fractional-order difference analog-to-digital converter according to claim 1, wherein the serialized bitstream generator comprises an event detector, an event register, a finite state machine, a bitstream clock generator, and a bitstream packer.

8. The fractional-order difference analog-to-digital converter according to claim 7, wherein the serialized bitstream generator, at a rising edge of each global clock CLKADC, uses the event detector to read the incremental value from the incremental counter and determine whether the incremental value forms a fractional-order incremental event; when the incremental value is not 0Δ, it is indicated that the currently acquired signal differs from the signal to be compared, and it is determined as a fractional-order incremental event; at this point, the incremental value is stored in the event register;
after all L channels complete one acquisition, one complete data acquisition frame is formed; each time one acquisition frame is completed, the finite state machine generates one enable signal ENA and inputs the enable signal ENA to the bitstream clock generator; the clock generator incorporates a ring oscillator specifically designed to provide a clock CLKBIT for bitstream packer;
then, the finite state machine scans the data in the event register and performs bitstream packer based on the CLKBIT clock to ultimately generate a FOD-ADC data bitstream.

9. The fractional-order difference analog-to-digital converter according to claim 1, wherein the DAC is implemented using an 8-bit capacitive voltage-dividing structure; and the comparator employs a dynamic comparator.

10. The fractional-order difference analog-to-digital converter according to claim 3, wherein the computation matrix comprises a series of multiplication units.
